(19) United States
(12) Patent Application Publication
(10) Pub. No.: US 2026/0150203 A1
(43) Pub. Date: May 28, 2026

(54) DISPLAY APPARATUS AND METHOD OF FABRICATING THE SAME

(71) Applicant: LG Display Co., Ltd., Seoul (KR)

(72) Inventor: Sung-Sik SON, Paju-si (KR)

(73) Assignee: LG Display Co., Ltd., Seoul (KR)

(21) Appl. No.: 19/323,602

(22) Filed: Sep. 9, 2025

(30) Foreign Application Priority Data
Nov. 28, 2024 (KR) 10-2024-0173715

(51) Int. Cl. H05K 5/00; H05K 5/02; H05K 7/20

(52) U.S. Cl. CPC H05K 5/0069; H05K 5/0217; H05K 7/20963

(57) ABSTRACT

A display apparatus and a method of fabricating the same are disclosed. The display apparatus comprises a display module including a source printed circuit board; a control printed circuit board on a rear surface of the display module; a fixing member for fixing the control printed circuit board to the display module and disposed on the rear surface of the display module; and a set frame combined to the rear surface of the display module and including a widow in correspondence to the fixing member, wherein the control printed circuit board is configured to be rotated by the fixing member, and wherein one end of the control printed circuit board is combined with the fixing member exposed through the window, and the set frame is disposed between a portion of the rear surface of the display module and the other end of the control printed circuit board.

### CROSS-REFERENCE TO RELATED APPLICATIONS

The present application claims the benefit of Korean Patent Application No. 10-2024-0173715 filed in the Republic of Korea on Nov. 28, 2024, which is hereby incorporated by reference in its entirety.

### BACKGROUND

### Technical Field

The present disclosure relates to a display apparatus, and more specifically, to a display apparatus being capable of being simply assembled with a set and a method of fabricating the same.

### Description of the Related Art

As information technology develops, various types of small and thin display apparatuses (e.g., display devices) such as a liquid crystal display device, an organic light emitting display device, a plasma display device, and micro-LED display device, are introduced.

These display devices are assembled and used with various electronic devices such as a smartphone and a tablet PC. When assembling the display device and the electronic device, the display device and the electronic device are electrically connected by a control printed circuit board. However, since the electrical connection between the display device and the electronic device is currently performed manually by workers, the assembly productivity of the display device and the electronic device is decreased. In addition, a problem of assembly defects occurs.

### BRIEF SUMMARY

The present disclosure is directed to a display apparatus and a method of fabricating the same that substantially obviate one or more of the problems associated with the limitations and disadvantages of the related conventional art.

An object of the present disclosure is to provide a display apparatus being capable of being simply assembled with a set.

An object of the present disclosure is to provide a method of fabricating a display apparatus being capable of being simply assembled with a set.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is a display apparatus comprising a display module including a source printed circuit board; a control printed circuit board on a rear surface of the display module; a fixing member for fixing the control printed circuit board to the display module and disposed on the rear surface of the display module; and a set frame combined to the rear surface of the display module and including a widow in correspondence to the fixing member, wherein the control printed circuit board is configured to be rotated by the fixing member, and wherein one end of the control printed circuit board is combined with the fixing member exposed through the window, and the set frame is disposed between a portion of the rear surface of the display module and the other end of the control printed circuit board.

Another aspect of the present disclosure is a method of fabricating a display apparatus comprising providing a display module including a fixing member; fixing a control printed circuit board to the fixing member; rotating the fixing member to dispose the control printed circuit board being perpendicular to the display module; combining a set frame to a rear surface of the display module, wherein the set frame includes a widow exposing the fixing member, and the control printed circuit board protrudes through the window; and rotating the fixing member to dispose the control printed circuit board being parallel to the set frame.

It is to be understood that both the foregoing general description and the following detailed description are exemplary and explanatory and are intended to further explain the present disclosure as claimed.

### BRIEF DESCRIPTION OF THE SEVERAL VIEWS OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a rear view of a display apparatus according to an embodiment of the present disclosure.

FIG. 2 is a side view of a display apparatus according to an embodiment of the present disclosure.

FIG. 3 is a flow chart illustrating a method of assembling a display apparatus according to an embodiment of the present disclosure.

FIG. 4 is a perspective view of a fixing member of a control printed circuit board of a display apparatus according to one embodiment of the present disclosure.

FIG. 5A is a drawing showing a first fixing member of a disassembled fixing member of a display apparatus according to one embodiment of the present disclosure.

FIG. 5B is a drawing showing a second fixing member of a disassembled fixing member of a display apparatus according to one embodiment of the present disclosure.

FIG. 6 is a view showing a disassembled fixing member of a display apparatus according to one embodiment of the present disclosure in which a first fixing member is coupled to a second fixing member and rotates.

FIGS. 7A to 7F are views showing a method for manufacturing a display apparatus according to the present disclosure.

FIG. 8 is a view showing a display apparatus according to the present disclosure in which a first fixing member is stopped by a stopper and a control printed circuit board is placed vertically to a display module.

FIG. 9 is a view showing the structure of a display apparatus according to another embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including,’ ‘having,’ ‘consisting,’ and the like are used in this specification, other parts may be added unless ‘only’ is used. When a component is expressed in the singular, cases including the plural are included unless specific statement is described.

The expression “at least one of a, b, and c” described throughout the specification can encompass ‘a alone,’ ‘b alone,’ ‘c alone,’ ‘a and b,’ ‘a and c,’ ‘b and c,’ or ‘all of a, b, and c.’ The advantages and features of the present disclosure, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

The area, length, or thickness of each component described in the specification is illustrated for convenience of explanation, and the present disclosure is not necessarily limited to the area and thickness of the illustrated component.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

In the present disclosure, the “display apparatus” may include a narrowly defined display apparatus such as a display module including a display panel and a driving unit for driving the display panel. In addition, the “display apparatus” may also include a set electronic device or a set apparatus such as a notebook computer, a television, a computer monitor, an automotive display, an equipment display, a smart phone or an electronic pad, being a complete product (or a final product) including a display module.

Accordingly, the display apparatus in the present disclosure may include a display apparatus in the narrow sense, such as a display module, and a set device, which is an application product or final consumer device including the display module.

Reference will now be made in detail to some of the examples and preferred embodiments, which are illustrated in the accompanying drawings.

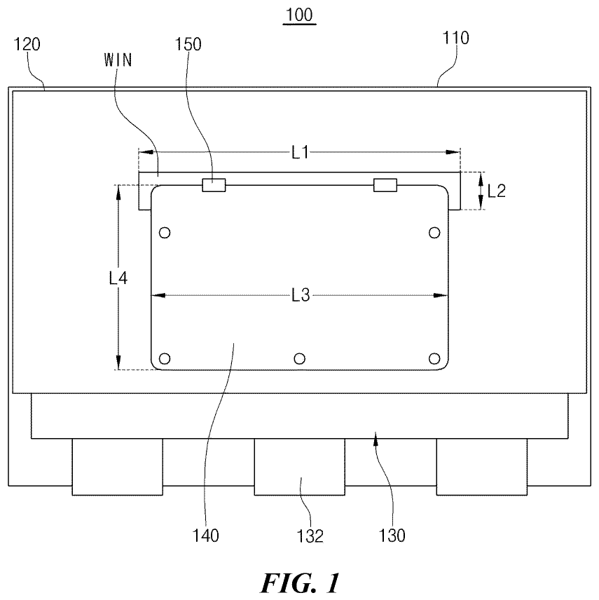

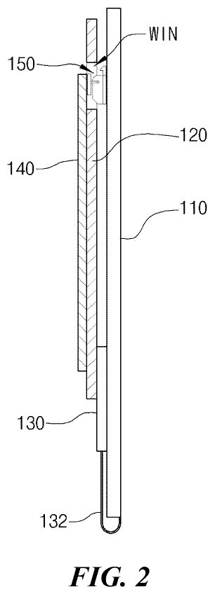

FIG. 1 is a rear view of a display apparatus according to an embodiment of the present disclosure, and FIG. 2 is a side view of a display apparatus according to an embodiment of the present disclosure.

As shown in FIGS. 1 and 2, a display apparatus 100 of the present disclosure includes a display module 110, a set frame 120 and a control printed circuit board (CPCB) 140. The display module 110 is coupled to the set frame 120. The CPCB 140 electrically connects the display module 110 to an external electronic product set, i.e., an external system. The set frame 120 may be a side frame of the electronic product set, i.e., the external system. The electronic product set may include at least one of various electronic devices, e.g., a smart phone, a laptop computer, a digital broadcasting terminal, a personal digital assistant (PDA), a portable multimedia player (PMP), a navigation device, a slate PC, a tablet PC, an ultrabook, a wearable device, such as a smartwatch, a smart glass, or a head mounted display (HMD).

The display module 110 includes a display panel, on which an image is displayed, a source printed circuit board (SPCB) 130 disposed on a rear surface of the display panel and a flexible circuit film 132 connecting the SPCB 130 to the display panel.

The display panel may be one of a liquid crystal panel, an organic light emitting display panel, a mini-LED display panel, an electrophoretic display panel and a micro-LED display panel, but it is not limited thereto.

The SPCB 130 is electrically connected to the display panel through the flexible circuit film 130 so that various signals are provide into the display panel. A signal line, a circuit element and a memory element may be mounted on the SPCB 130. For example, a circuit element, e.g., an image processing unit, a timing control unit or a power supply unit, may be mounted on the SPCB 130.

The image processing unit outputs image data supplied from an external system and a driving signal for driving various devices. For example, the driving signal from the image processing unit may include a data enable signal, a vertical synchronization signal, a horizontal synchronization signal, and a clock signal.

The timing control unit receives the image data and the driving signal from the image processing unit. The timing control unit generates and outputs a gate timing control signal (GDC) and a data timing control signal (DDC) based on the drive signal from the image processing unit. The power supply unit outputs high-potential voltage (VDD) and low-potential voltage (VSS) to the display panel.

The SPCB 130 is connected to the display panel through a flexible circuit film 132. The flexible circuit films 132 are arranged at a pre-determined interval. One end of the flexible circuit film 132 is attached to a pad area of the display panel, and the other end of the flexible circuit film 132 is disposed on the SPCB 130.

Various signal lines are formed on the flexible circuit film 132 to electrically connect the display panel and the SPCB 130. Accordingly, the signals generated by the circuit elements mounted on the SPCB 130 is applied to the display panel. A data driving element is mounted on the SPCB 130 to output a data voltage to the display panel in response to a data timing control signal (DDC) from the timing control unit.

The flexible circuit film 132 may be a tape carrier package (TCP) or a chip on film (CF), but it is not limited thereto.

The CPCB 140 electrically connects the external system and the SPCB 130 to supply the image data of the external system to the SPCB 130. Although not shown, a connector is formed at both ends of the CPCB 140. The connector at one end of the CPCB 140 is connected to the connector of the SPCB 130, and the connector at the other one end of the CPCB 140 is connected to the connector of the external system.

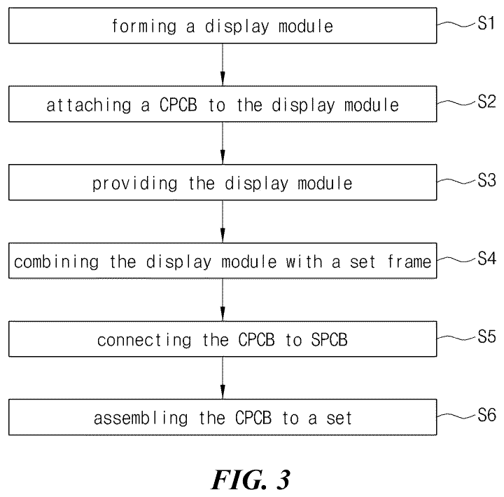

FIG. 3 is a flow chart illustrating a method of assembling a display apparatus according to an embodiment of the present disclosure.

As shown in FIG. 3, a display module is provided or formed (step S1). In the step S1, one end of a flexible circuit film 132 is attached to a pad area of a display panel, and a SPCB 130 is attached to the other end of the flexible circuit film 132. The SPCB 130 is bended toward a rear side of the display panel to provide the display module.

The display panel may include various elements, e.g., a thin film transistor (TFT), various electrodes and a display element, on a substrate. The display element may include one of a liquid crystal display element, an organic electroluminescent display element, an electrophoretic display element, a mini-LED display element and a micro-LED display element, but it is not limited thereto.

Next, a CPCB 140 is attached on a rear side of the display module 110 (Step S2). As described below, the CPCB 140 is attached on the rear side of the display module 110 by a fixing member 150 (or fastener assembly 150) on the rear surface of the display module.

The display module 110, on which the CPCB 140 is attached, is provided into a next process (Step S3). For example, the display module 110, on which the CPCB 140 is attached, is provided into a set company.

Next, the display module 110 is combined to a set frame 120 of a set (Step S4).

Next, the CPCB 140 and the SPCB 130 are electrically connected (Step S5). The CPCB 140 and the set are electrically connected and assembled (Step S6). The step S5 and the step S6 may be simultaneously performed. Alternatively, the step S6 may be performed before the step S5.

As described below, in the display apparatus 100 of the present disclosure, after the CPCB 140 is fixed to the display module 110, the CPCB 140 may be electrically connected to the set.

When the CPCB 140 is fixed to the display module 110 by using a double-sided tape, the CPCB 140 fixed by the double-sided tape may be separated from the display module 110, and the set frame 120 and the display module 110 may be combined. Then, the CPCB 140 may be re-combined to the display module 110 and electrically connected to the set.

However, in the display apparatus 100 of the present disclosure, the fixing member 150 is provided on the display module 110 to fix the CPCB 140 to the display module 110. In particular, the display apparatus 100 can be quickly fabricated by combining the set frame 120 and the display module 110 without separating the CPCB 140 from the display module 110.

Referring again to FIGS. 1 and 2, a window WIN (e.g., an opening) is formed in the set frame 120 coupled to the display module 110 such that a portion of the rear surface of the display module 110 is exposed to the outside through the window WIN. In this instance, a horizontal length L1 of the window WIN may be greater than a horizontal length L3 of the CPCB 140. A vertical length L2 of the window WIN may be greater than a thickness of the CPCB 140. As a result, the CPCB 140 can pass through the window WIN. The vertical length L2 of the window WIN may be smaller than a vertical length L4 of the CPCB 140.

In the display apparatus 100, one end of the CPCB 140 is combined with the fixing member 150 exposed through the window WIN, and the set frame 120 is disposed between a portion of the rear surface of the display module 100 and the other end of the CPCB 140.

At least two fixing members 150 are disposed on the rear surface of the display module 110 exposed through the window WIN. A part of the CPCB 140 is fixed to the display module 110 exposed to the outside through the window WIN of the set frame 120 by the fixing members 150, but the remaining part of the CPCB 140 is disposed outside the set frame 120.

In the display apparatus 100 of the present disclosure, since the CPCB 140 is rotatably fixed to the fixing member 150, the display module 110 and the set frame 120 can be combined without separating the CPCB 140 from the display module 110. This will be described in detail below.

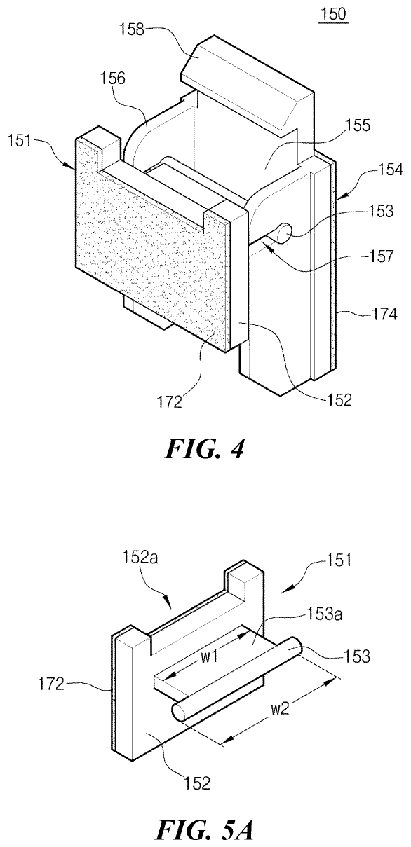

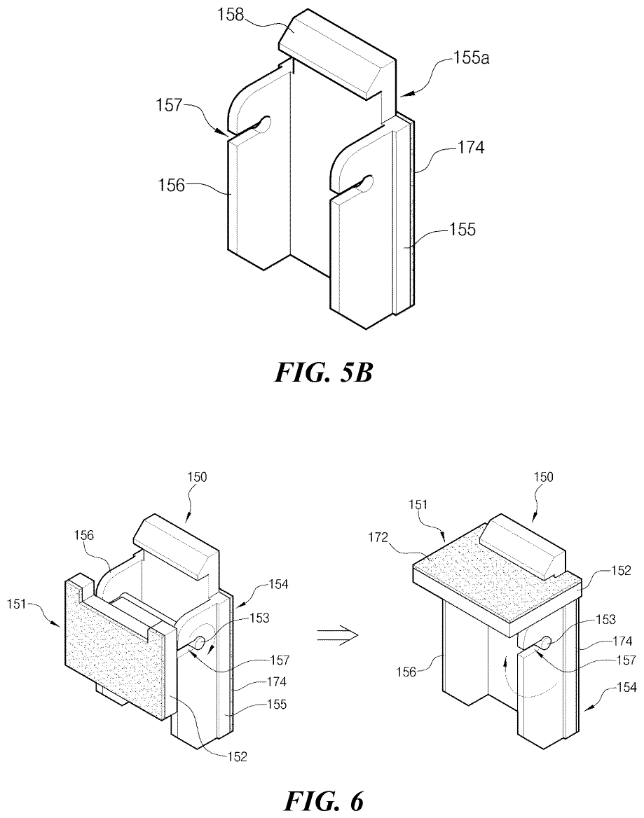

FIG. 4 is a perspective view of a fixing member of a control printed circuit board of a display apparatus according to one embodiment of the present disclosure. FIG. 5A is a drawing showing a first fixing member of a disassembled fixing member of a display apparatus according to one embodiment of the present disclosure, and FIG. 5B is a drawing showing a second fixing member of a disassembled fixing member of a display apparatus according to one embodiment of the present disclosure.

As shown in FIGS. 4, 5A and 5B, the fixing member 150 of the display apparatus 100 of the present disclosure includes a first fixing member 151 (first fastener 151) and a second fixing member 154 (second fastener 154). The first fixing member 151 and the second fixing member 154 are coupled to each other to fix the CPCB 140 to the display module 110.

The CPCB 140 is fixed to the first fixing member 151, and the second fixing member 154 is fixed to the rear surface of the display module 110.

The first fixing member 151 includes a support member 152 supporting a CPCB 140, an extension member 153a downwardly extending from the support member 152 and a rotation member 153 disposed at an end of the extension member 153a. In other words, the extension member 153a extends from the support member 152 to be perpendicular to a surface of the support member 152. A width W1 of the extension member 153a is smaller than a width W2 of the rotation member 153.

The second fixing member 154 includes a base 155 facing the rear surface of the display module 110, two side members 156 (e.g., a first side member and a second side member) upwardly extending from both sides of the base 155, an opening 157 in each of the two side members 156 and a stopper 158 upwardly extending from one end of the base 155. Namely, the two side members 156 upwardly extends from first and second sides, which are opposite to each other, of the base 155, and the stopper 158 upwardly extends from a third side, which connects the first and second sides, of the base 155.

The support member 152 of the first fixing member 151 is configured as a flat surface and supports one side of the CPCB 140 when fixing the CPCB 140 to the display module 110. In this instance, a first adhesive member 172 is disposed on an upper surface of the support member 152. The CPCB 140 can be attached to the support member 152 by the first adhesive member 172. The first adhesive member 172 may be a double-sided tape, but it is not limited thereto.

The rotating member 153 is disposed at one end of the extension member 153a and inserted into the opening 157 of the second fixing member 154. The rotating member 153 may have a cylindrical shape. The rotating member 153 is disposed along the horizontal direction of the support member 152 and inserted into two openings 157 of the second fixing member 154. In this instance, a diameter of the opening 157 is larger than that of the rotating member 153 so that the rotating member 153 is rotatably inserted into the opening 157.

In FIGS. 4 and 5A, the rotating member 153 has a cylindrical shape with a circular cross section, but it is not limited thereto. In an aspect of the present disclosure, the rotating member 153 may have other shape, e.g., as an oval shape.

The base 155 supports the side member 156 where the opening 157 is formed, and is attached to the rear surface of the display module 110. In this instance, a second adhesive member 174 is provided on an outer side of the base 155. The second adhesive member 174 is provided between the base 155 and the display module 110 to attach the fixing member 150 to the rear surface of the display module 110. For example, the second adhesive member 174 may be a double-sided tape, but it is not limited thereto.

In the present disclosure, since the rotating member 153 is provided, the first fixing member 151 rotates. In addition, as the first fixing member 151 rotates, the CPCB 140 fixed to the first fixing member 151 rotates. The rotating member 153 can rotate 90 degrees in the clockwise direction. As the rotating member 153 rotates 90 degrees in the clockwise direction, the CPCB 140 fixed to the first fixing member 151 can be arranged vertically to the rear surface of the display module 110.

The stopper 158 is formed by protruding from the base 155 by a pre-determined height from the end of the base 155. One end of the stopper 158 protrudes toward the first fixing member 151. As described below, the stopper 158 stops the rotation of the first fixing member 151 and contacts with a front surface (e.g., an opposite surface of the surface attached to the support member 152 of the first fixing member 151) of the CPCB 140, which rotates together with the first fixing member 151. A distance between the side member 156 and the stopper 158 is equal to larger than a thickness summation of the support member 152 and the CPCB 140.

The end of the stopper 158 may be perpendicular to the base 155, but it is not limited thereto. For example, when the stopper 158 is perpendicular to the base 155, the CPCB 140 is vertically arranged to the display module 110 when the first fixing member 151 is rotated and stopped by the stopper 158. In an embodiment of the present disclosure, when the stopper 158 is arranged at an acute angle to the base 155, the CPCB 140 can be arranged at an acute angle to the display module 110. In an embodiment of the present disclosure, when the stopper 158 is arranged at an obtuse angle to the base 155, the CPCB 140 can be arranged at an obtuse angle to the display module 110.

The support member 152 and the base 155 face to each other. A first surface of the support member 152 and a first surface of the base 155 face to each other. The first adhesive member 172 is disposed on a second surface of the support member 152, which is opposite to the first surface of the support member 152, and the second adhesive member 174 is disposed on a second surface of the base 155, which is opposite to the first surface of the base 155.

The extension member 153a protrudes (or extends) from the first surface of the support member 152, and the two side members 156 (e.g., two side walls) protrude (or extend) from the first surface of the base 155. Namely, the extension member 153a protrudes from the support member 152 toward the base 155, and the two side members 156 protrude from the base 155 toward the support member 152. The extension member 153a, the rotation member 153, the two side members 156 are disposed between the support member 152 and the base 155.

The opening 157 is formed on a portion of a top surface of each of the two side members 156 toward the base 155. The support member 152 is connected to one end of the extension member 153a, and the rotation member 153 is connected to the other end of the extension member 153a. A length of the extension member 153a is equal to or smaller than a distance between the two side members 156. Both ends of the rotation member 153 can be inserted into the opening 157 in each of the two side members 156 so that the extension member 153a is disposed between the two side members 156. Accordingly, the support member 152 can be rotated toward the base 155 or the stopper 158 using the rotation member 153 as a rotation axis. A distance between each of the two side members 156 and the stopper 158 may be equal to or larger than a thickness summation of the support member 152 and the CPCB 140. The distance between the two side members 156 may be equal to smaller than a width (e.g., a horizontal length) of the support member 152. As a result, the support member 152 can be supported by the side members 156 when the support member 152 is vertically positioned with respect to the base 155. A side of the support member 152 may include a groove 152a. A width of the groove 152a may be equal to or larger than a width of an end 155a of the base 155. As a result, the end 155a of the base 155 may be inserted into the groove 152a of the side of the support member 152. In other words, the neck of the stopper 158 and the groove 152a of the support member 152 may be coupled when the support member 152 is vertically positioned with respect to the base 155.

FIG. 6 is a view showing a disassembled fixing member of a display apparatus according to one embodiment of the present disclosure in which a first fixing member is coupled to a second fixing member and rotates.

As shown in FIG. 6, the rotation member 153 of the first fixing member 151 is inserted into the opening 157 of the second fixing member 154 so that the first fixing member 151 and the second fixing member 154 are coupled. In this instance, the rear surface of the CPCB 140 is attached to the support member 152 of the first fixing member 151, and the base 155 of the second fixing member 154 is attached to the display module 110.

Since the diameter of the opening 157 is larger than that of the rotation member 153, the rotation member 153 rotates freely when the rotation member 153 is inserted into the opening 157. As the rotation member 153 rotates clockwise, the supporting member 152 connected to the rotation member 153 through the extension member 153a also rotates so that the supporting member 152 is vertically arranged to the base 155.

In the display apparatus 100 of the present disclosure, since the CPCB 140 is fixed to the display module 110 by the fixing member 150 including the rotatable first fixing member 151, the display apparatus 100 can be coupled to the set frame 120 without separating the CPCB 140.

A method of coupling a display apparatus 100 to a set frame 120 is described in more detail.

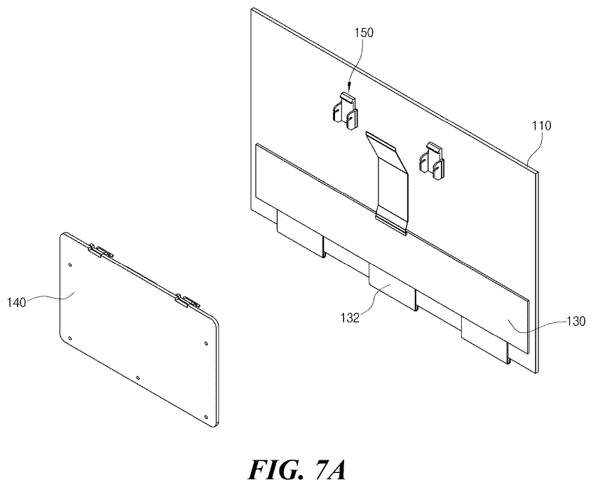

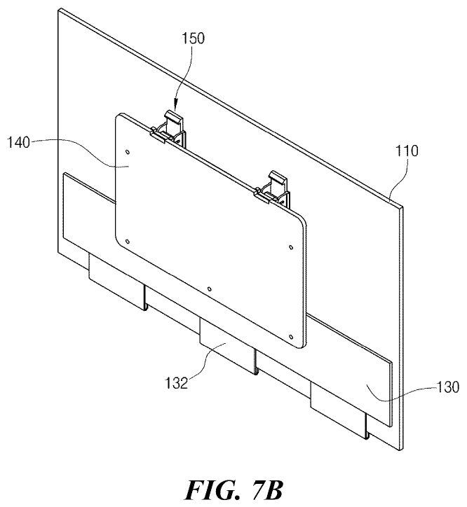

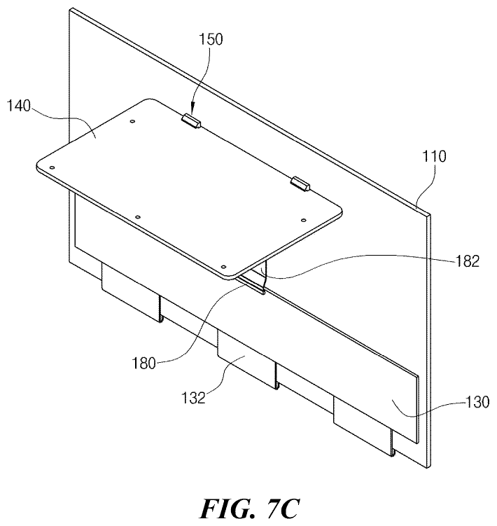

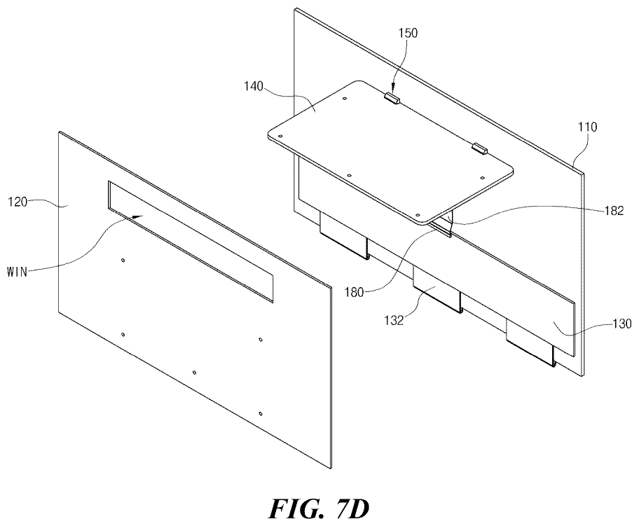

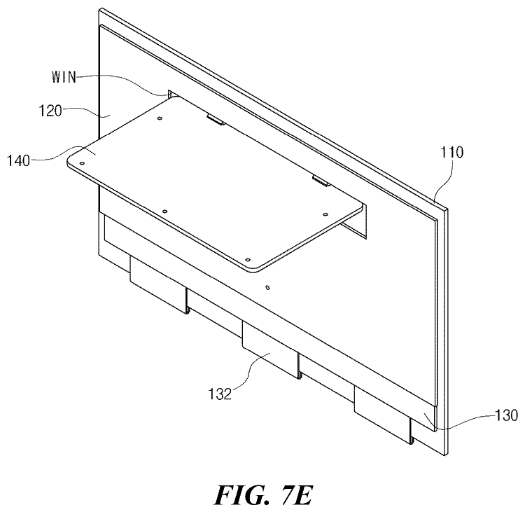

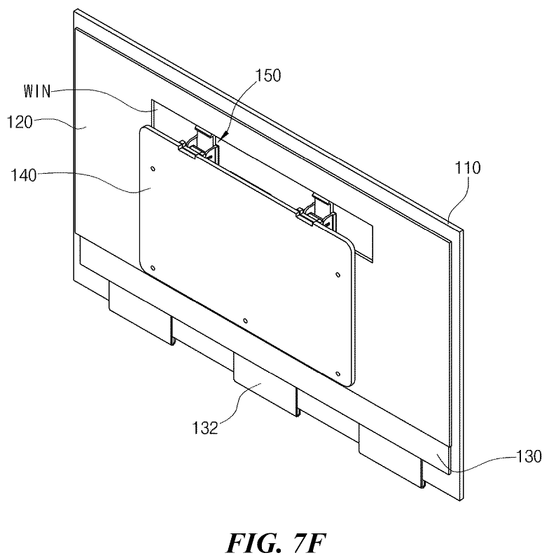

FIGS. 7A to 7F are views showing a method for manufacturing a display apparatus according to the present disclosure.

As shown in FIG. 7A, at least two fixing members 150 are attached to the rear surface of the display module 110. In this instance, a plurality of flexible circuit films 132 are arranged on one side of the rear surface of the display module 110, and a SPCB 130 is arranged on the rear surface of the display module 110. The SPCB 130 may be disposed to be adjacent to the flexible circuit films 132. One end of the flexible circuit film 132 is attached to the pad area of the display module 110, and the other end of the flexible circuit film 132 is attached to the SPCB 130.

The base 155 of the second fixing member 154 is attached to the rear surface of the display module 110 by the second adhesive member 174 while the first fixing member 151 and the second fixing member 154 are combined. As a result, the fixing member 150 is attached to the rear surface of the display module 110.

Next, as shown in FIG. 7B, the CPCB 140 is attached to the fixing member 150. In this instance, the CPCB 140 is attached to the support member 152 of the first fixing member 151 by the first adhesive member 172.

Next, as shown in FIG. 7C, the first fixing member 151 is rotated clockwise so that the CPCB 140 is disposed to be perpendicular to the display module 110.

In this instance, the CPCB 140 and the SPCB 130 are electrically connected to each other by a connection cable 180. One end of the connection cable 180 is inserted into a connector 182 of the SPCB 130, and the other end of the connection cable 180 is inserted into a connector (not shown) of the CPCB 140. As a result, the CPCB 140 and the SPCB 130 are electrically connected to each other

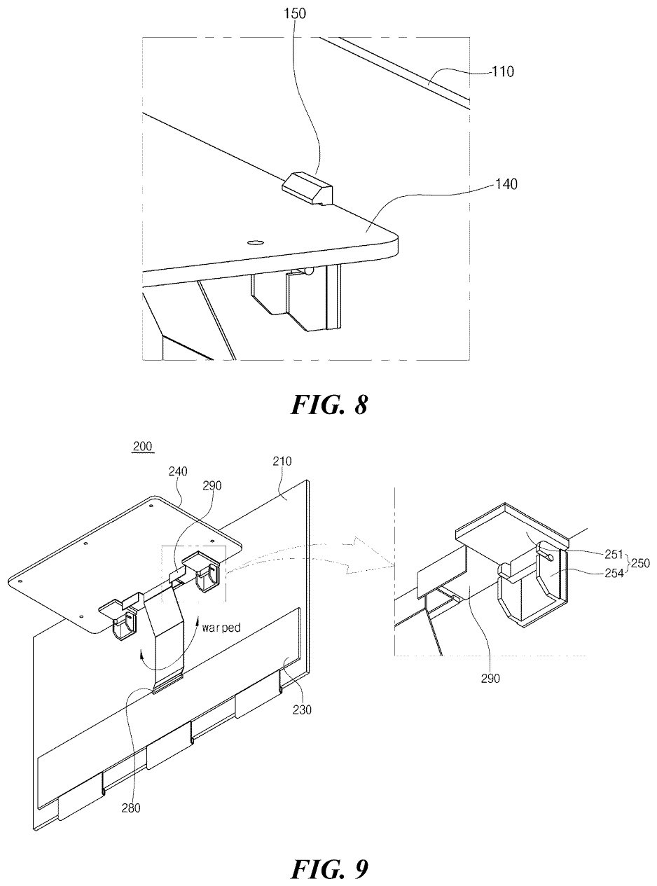

Referring to FIG. 8, when the first fixing member 151 rotates clockwise, the front surface of the CPCB 140, which is attached to the first fixing member 151, comes into contact with the stopper 158. As a result, the rotation of the first fixing member 151 stops at 90 degrees, and the CPCB 140 is positioned to be perpendicular to the display module 110.

Next, as shown in FIGS. 7D and 7E, with the CPCB 140 vertically positioned on the display module 110, the set frame 120 is attached to the rear surface of the display module 110 by a first coupling member. The first coupling member may be a screw or a double-sided tape, but it is not limited thereto. When the set frame 120 is attached to the rear surface of the display module 110, the vertically placed CPCB 140 passes through the window WIN in the set frame 120.

Next, as shown in FIG. 7F, the first fixing member 151 is rotated counterclockwise so that the CPCB 140 faces the set frame 120, which is coupled to the rear surface of the display module 110. Then, the CPCB 140 is fixed by a second coupling member. The second coupling member may be a screw, but it is not limited thereto.

As described above, in the display apparatus of the present disclosure, the CPCB 140 is fixed by the rotatable fixing member 150, which is attached to the rear surface of the display module 110, so that the set frame 120 can be assembled to the rear surface of the display module 110 without separating the CPCB 140. Accordingly, the assembly time of the display apparatus can be significantly shortened. In addition, since an additional fixing member, such as double-sided tape, for fixing the CPCB to the display module is not required, unnecessary costs can be reduced and contamination due to disposal of the double-sided tape can be prevented.

FIG. 9 is a view showing the structure of a display apparatus according to another embodiment of the present disclosure. The description of the same structure as the display apparatus 100 of the embodiment illustrated in FIG. 4 is omitted or briefly explained. The description is focused on a different structure.

As shown in FIG. 9, in the display apparatus 200, a plurality of heat dissipation members 290 are arranged on the rear surface of the CPCB 240. The rear surface of the CPCB 240 is a surface facing the rear surface of the display module 210. FIG. 9 shows two heat dissipation members 290 arranged one by one near the fixing member 250, but it is not limited thereto.

One side of the heat dissipation member 290 is attached to the rear surface of the display module 210, and the other side of the heat dissipation member 290 is attached to the CPCB 240. Heat generated from the CPCB 240 can be dissipated to the outer frame of the display module 210 through the heat dissipation member 290, and the heat of the outer frame of the display module 210 can be dissipated to the outside. The heat dissipation member 290 can be attached to the display module 210 and the CPCB 240 by a thermally-conductive adhesive member. The thermally-conductive adhesive member may be a thermally-conductive double-sided tape, but it is not limited thereto.

In addition, the heat dissipation member 290 may have a bending shape, e.g., a “Γ” shape, to facilitate thermal contact between the heat dissipation member 290 and the display module 210. However, the shape of the heat dissipation member 290 is not limited thereto. As long as the heat dissipation member 290 can make sufficient contact with the display module 210, the heat dissipation member 290 can be formed in any shape. The heat dissipation member 290 can be formed of a metal with sufficient thermal conductivity. For example, the heat dissipation member 290 may be formed of aluminum (Al), but it is not limited thereto.

In addition, the heat dissipation member 290 may act as another fixing member that fixes the CPCB 240 to the display module 210. Referring to FIG. 7E, when the set frame 120 is assembled with the CPCB 140 vertically disposed to the display module 110, the CPCB 140 should pass through the window WIN of the set frame 120. If the CPCB 140 is not firmly fixed and is misaligned, the CPCB 140 cannot pass through the window WIN of the set frame 120. As a result, it may be impossible to assemble the set frame 120 with the display apparatus 100.

The CPCB 140 is fixed to the display module 110 by the fixing member 150, but the CPCB 140 may become warped (or twisted) by an external force.

However, in the display apparatus 200 of the present disclosure, the CPCB 240 is further attached to the display module 210 by the heat dissipation member 290 as a fixing member so that the warping problem of the CPCB 240 can be prevented. Accordingly, the assemble of the display apparatus 200 can be further secured.

It will be apparent to those skilled in the art that various modifications and variations can be made in the embodiments of the present disclosure without departing from the spirit or scope of the present disclosure. Thus, the disclosure covers the modifications and variations of the concepts provided herein. The claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display module including a source printed circuit board;
a control printed circuit board on a rear surface of the display module;
a fixing member for fixing the control printed circuit board to the display module and disposed on the rear surface of the display module; and
a set frame coupled to the rear surface of the display module and including a window corresponding to the fixing member,
wherein the control printed circuit board is configured to be rotated by the fixing member, and
wherein an end of the control printed circuit board is coupled to the fixing member exposed through the window, and the set frame is disposed between a portion of the rear surface of the display module and an opposite end of the control printed circuit board.

2. The display apparatus according to claim 1, wherein the fixing member includes a first fixing member attached to the control printed circuit board and a second fixing member attached to the rear surface of the display module, and
wherein the first fixing member is rotatably coupled to the second fixing member.

3. The display apparatus according to claim 2, wherein the first fixing member includes:
a support member supporting the control printed circuit board;
an extension member extending from the support member; and
a rotation member disposed at an end of the extension member.

4. The display apparatus according to claim 3, wherein the rotation member has a cylindrical shape.

5. The display apparatus according to claim 3, wherein the second fixing member includes:
a base attached to the rear surface of the display module;
first and second side members respectively extending from two sides of the base; and
an opening through each of the first and second side members,
wherein the rotation member is inserted into the opening.

6. The display apparatus according to claim 5, wherein a diameter of the opening is greater than a diameter of the rotation member, and the rotation member is configured to rotate in the opening.

7. The display apparatus according to claim 5, wherein a width of the extension member is less than a width of the rotation member and the width of the extension member is equal to or less than a distance between the first and second side members.

8. The display apparatus according to claim 5, wherein the second fixing member further includes a stopper at an end of the base,
wherein a rotation of the rotation member is limited by the stopper.

9. The display apparatus according to claim 8, wherein a distance between each the first and second side members and the stopper is equal to or greater than a sum of a thickness of the support member and the control printed circuit board.

10. The display apparatus according to claim 5, wherein the first fixing member further includes a first adhesive member disposed on the support member, and the second fixing member further includes a second adhesive member disposed on the base, and
wherein the control printed circuit board is coupled to the first fixing member through the first adhesive member, and the second fixing member is coupled to the display module through the second adhesive member.

11. The display apparatus according to claim 10, wherein at least one of the first and second fixing members is a double-sided tape.

12. The display apparatus according to claim 1, further comprising a heat dissipation member,
wherein an end of the heat dissipation member is coupled to the control printed circuit board, and an opposite end of the heat dissipation member is coupled to the display module.

13. The display apparatus according to claim 12, wherein the control printed circuit board is fixed by the heat dissipation member.

14. The display apparatus according to claim 12, wherein the heat dissipation member is metal.

15. A method of fabricating a display apparatus, comprising:
providing a display module including a fixing member;
fixing a control printed circuit board to the fixing member;
rotating the fixing member to dispose the control printed circuit board perpendicular to the display module;
coupling a set frame to a rear surface of the display module, wherein the set frame includes a window exposing the fixing member, and the control printed circuit board protrudes through the window; and
rotating the fixing member to dispose the control printed circuit board parallel to the set frame.

16. The method according to claim 15, wherein the fixing member includes a first fixing member attached to the control printed circuit board and a second fixing member attached to the rear surface of the display module, and
wherein the first fixing member is rotatably coupled to the second fixing member.

17. The method according to claim 16, wherein the first fixing member includes:
a support member supporting the control printed circuit board;
an extension member extending from the support member; and
a rotation member disposed at an end of the extension member.

18. The method according to claim 17, wherein the rotation member has a cylindrical shape.

19. The method according to claim 17, wherein the second fixing member includes:
a base attached to the rear surface of the display module;
first and second side members respectively extending from two sides of the base; and
an opening through each the first and second side members,
wherein the rotation member is inserted into the opening.

20. The method according to claim 19, wherein the second fixing member further includes a stopper at an end of the base,
wherein a diameter of the opening is greater than a diameter of the rotation member, and the rotation member is configured to rotate in the opening,
wherein a width of the extension member is less than a width of the rotation member and the width of the extension member is equal to or smaller than a distance between the first and second side members, and
wherein a distance between each of the first and second side members and the stopper is equal to greater than a sum of a thickness of the support member and the control printed circuit board.
